(19) United States
(12) Patent Application Publication
(10) Pub. No.: US 2006/0138905 A1
(43) Pub. Date: Jun. 29, 2006

(54) Piezoelectric fan for an integrated circuit chip

(76) Inventors: Christopher A. Gonzales, Chandler, AZ (US); Leija Javier, Chandler, AZ (US); James C. Shipley, Gilbert, AZ (US); Chris D. Lucero, Chandler, AZ (US)

Correspondence Address: BUCKLEY, MASCHOFF, TALWALKAR LLC, 5 ELM STREET, NEW CANAAN, CT, 06840, US

(21) Appl. No.: 11/024,297

(22) Filed: Dec. 28, 2004

(51) Int. Cl. H01L 41/08

(52) U.S. Cl. 310/331

(57) ABSTRACT

According to some embodiments, a piezoelectric fan is attached to an integrated circuit chip. The piezoelectric fan may, for example, be soldered to the chip and receive power through a via of the integrated circuit chip.

### BACKGROUND

An integrated circuit generates heat as it operates, and the performance and reliability of the integrated circuit may decrease as the temperature rises. For example, an integrated circuit might operate more slowly or become damaged when it becomes too hot. To reduce this effect, a motorized fan heatsink (e.g., a blower) or liquid cooling system may be provided to lower the integrated circuit's temperature. In either case, the moving parts associated with the cooling system may fail. In addition, the location of the integrated circuit and surrounding components might make such solutions impractical. Moreover, the sound and/or electromagnetic noise produced by these cooling systems may be undesirable.

### BRIEF DESCRIPTION OF THE DRAWINGS

FIG. 1 is a block diagram of an apparatus according to some embodiments.

FIG. 2 is a perspective view of the apparatus according to some embodiments.

FIG. 3 illustrates a flexed piezoelectric device according to some embodiments.

FIG. 4 is a block diagram of an apparatus according to some embodiments.

FIG. 5 is a block diagram of a system according to some embodiments.

FIG. 6 is a flow diagram illustrating a method that may be performed by a control circuit according to some embodiments.

FIG. 7 is a block diagram of an apparatus according to some embodiments.

FIG. 8 is a block diagram of a system including a piezoelectric fan according to some embodiments.

### DETAILED DESCRIPTION

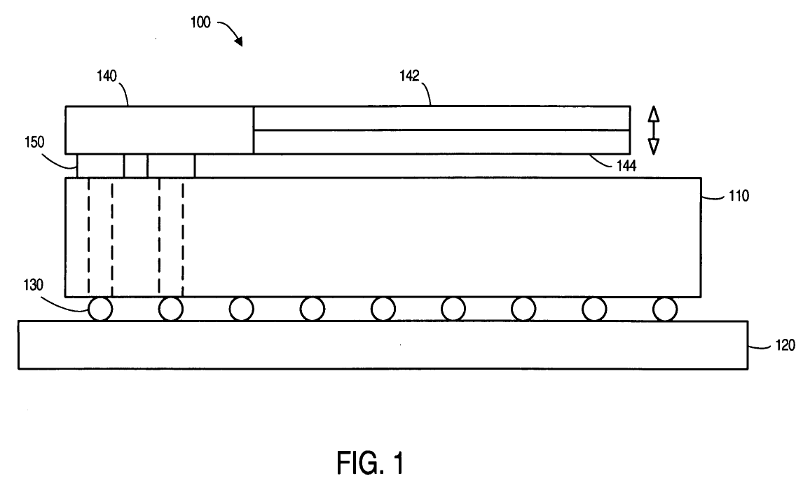

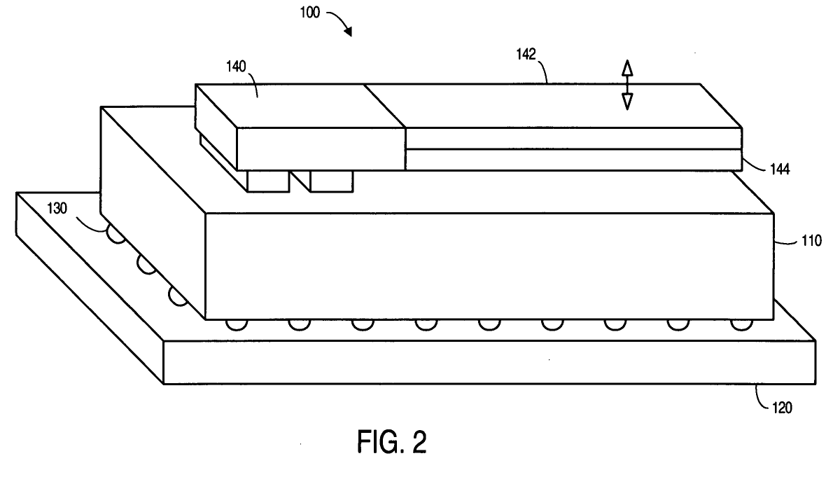

FIG. 1 is a block diagram of an apparatus 100, and FIG. 2 is a perspective view of the apparatus 100, according to some embodiments. The apparatus 100 may include an Integrated Circuit (IC) chip 110 mounted on a Printed Circuit Board (PCB) 120 (e.g., a motherboard) via solder ball joints 130. The IC chip 110 may be, for example, a processor such as an INTEL® PENTIUM® 4 processor. The IC chip 110 might also be a memory unit, such as a Random Access Memory (RAM) unit. The apparatus 100 might be associated with, for example, a Personal Computer (PC), a mobile computer, a Personal Digital Assistant (PDA), a network router, a wireless telephone, a media player, and/or a gaming device.

The IC chip 110 may generate heat as it operates, and the performance and reliability of the apparatus 100 may decrease as the temperature rises. To some extent, natural convention may transfer heat from the IC chip 110 to the surrounding air. As the temperature of the air surrounding the IC chip 110 increases, however, the amount of heat that is transferred in this way may be reduced.

According to some embodiments, a piezoelectric fan 140 may be attached to the IC chip 110. The piezoelectric fan 140 may be, for example, attached directly to the package of the IC chip 110 with solder joints 150 and/or glue. Note that the size of the piezoelectric fan 140 in FIG. 1 is merely an example, and an actual fan might be smaller or larger than illustrated (e.g., a fan might be 100 microns long).

The piezoelectric fan 140 may include a blade having a substrate 144. The substrate 144 may be, for example, a flexible, non-conducting material such as Mylar. A piezoelectric portion 142 may be attached to one side of the substrate 144. The piezoelectric portion 142 may comprise, for example, a ceramic material that expands or contracts in response to an electric current. Although the piezoelectric portion 142 illustrated in FIG. 1 extends along the length of the substrate, the portion might cover less than all of the substrate (e.g., a patch of piezoelectric material might be attached to one side of the substrate 144).

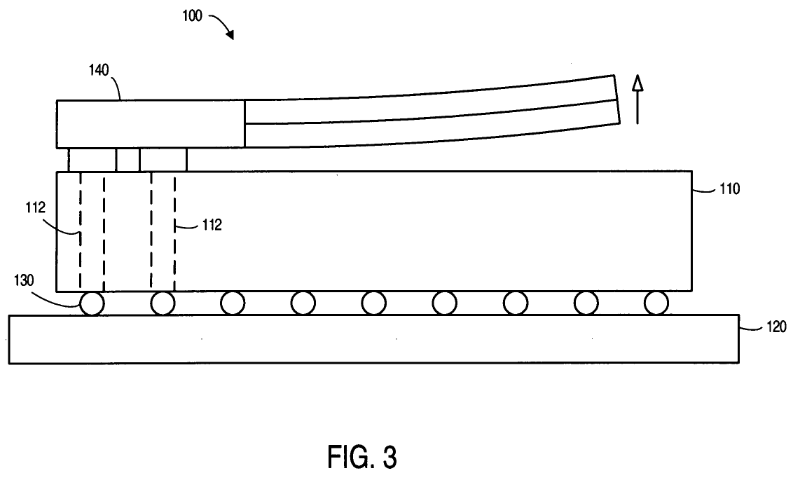

When an electric current flows through the piezoelectric portion 142 in one direction, the piezoelectric portion 142 may contract causing the blade to flex upward (away from the IC chip 110) as illustrated in FIG. 3. Similarly, when an electrical current flows through the piezoelectric portion 142 in the opposite direction, the piezoelectric portion 142 may expand causing the blade to flex downward (toward the IC chip 110). Thus, when Alternating Current (AC) power is provided to the piezoelectric fan 140 at an appropriate frequency (e.g., substantially near a resonant frequency), the blade may oscillate or vibrate. The appropriate frequency may depend on, for example, the sizes, materials, and proportions associated with the blade.

The AC power may be provided to the piezoelectric fan 140, for example, through one or more vias 112 of the IC chip 110. For example, power may be provided from a power plane of the PCB 120 to the piezoelectric fan 140 through a pin and/or a package solder ball 130 associated with the IC chip 110. By providing AC power to the piezoelectric fan 140 through a via of the IC chip 110, the design of the apparatus 100 may be simplified. According to another embodiment, a lead wire may provide AC power from a power plane of the PCB 120 (or another source) to the piezoelectric fan 140.

The movement of the blade may create an airflow near the surface of the IC chip 110 and facilitate a transfer of heat away from the IC chip 110 through forced convection. As a result, the performance and/or reliability of the apparatus 100 may be improved. Moreover, no motor or pump might be required, the piezoelectric fan 140 may be relatively quiet, and an amount of electromagnetic noise associated with the apparatus 100 may be reduced as compared to a cooling system that uses a motorized blower/fan or liquid pump.

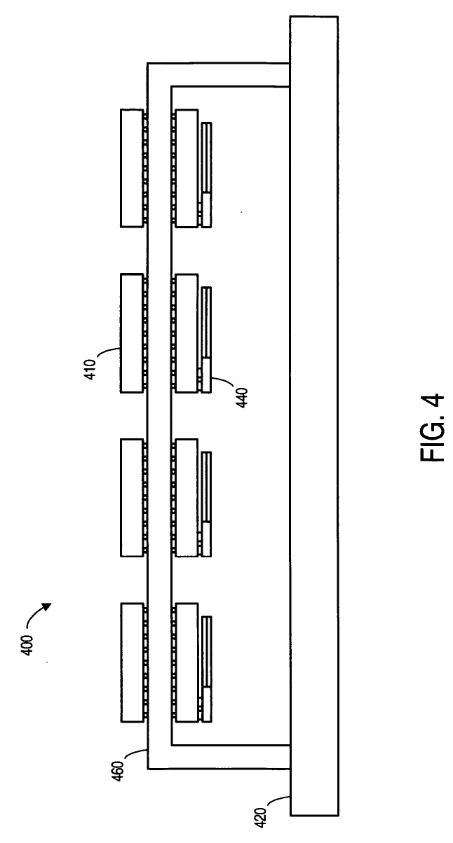

Note that the piezoelectric fan 140 might be used even when the location of the IC chip 110 and/or surrounding components makes the use of a motorized blower or liquid cooling system impractical. For example, FIG. 4 is a block diagram of an apparatus 400 according to some embodiments. In this case, a Small Outline Dual In-Line Memory Module (SODIMM) 460 is mounted on a PCB 420. The SODIMM 460 includes a number of IC chips 410, such as Synchronous Dynamic (SDRAM) units or Double Data Rate (DDR) SDRAM units. According to this embodiment, the IC chips 410 located on the underside of the SODIMM 460 have piezoelectric fans 440 while those on top do not (e.g., because natural convection may be sufficient or a conventional blower might be provided for those IC chips 410).

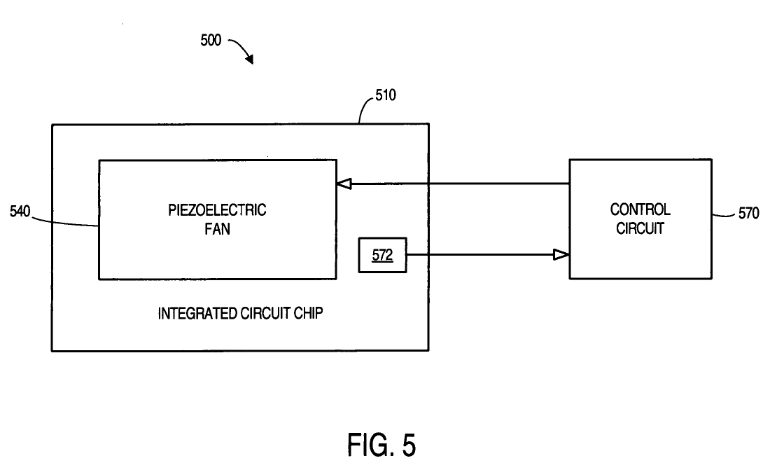

According to some embodiments, power is provided to a piezoelectric fan whenever power is applied to an IC chip. According to other embodiments, a piezoelectric fan is activated based on a temperature associated with an IC chip. For example, FIG. 5 is a block diagram of a system 500 according to some embodiments. As before, a piezoelectric fan 540 is attached to an IC chip 510. In this case, however, a control circuit 570 determines when the piezoelectric fan 440 will be activated. For example, the control circuit 570 might receive from a sensor 572 a signal associated with the temperature of the IC chip 540 and/or the surrounding air. When the temperature rises above a pre-determined threshold, the control circuit 570 might turn on the piezoelectric fan 540. Similarly, when the temperature falls below a threshold, the control circuit 570 might turn off the piezoelectric fan 540. Note that the control circuit 570 and/or sensor 572 might be separate from both the IC chip 510 and the piezoelectric fan 540. According to some embodiments, the control circuit 570 and/or sensor 572 are formed integral with the IC chip 510 and/or piezoelectric fan 540.

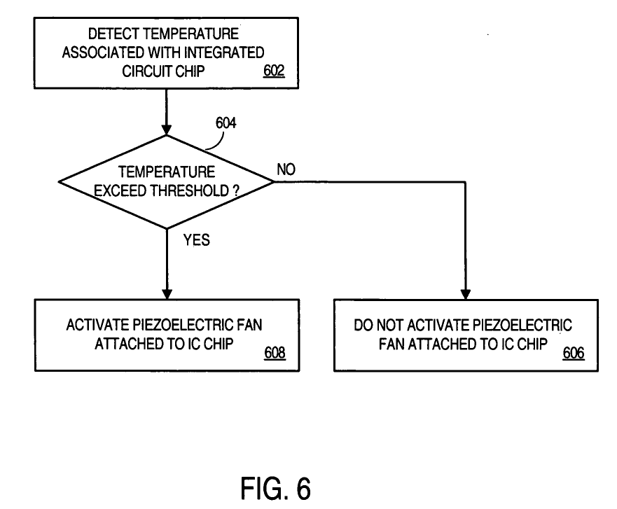

FIG. 6 is a flow diagram illustrating a method according to some embodiments. The flow chart does not necessarily imply a fixed order to the actions, and embodiments may be performed in any order that is practicable. Note that any of the methods described herein may be performed by hardware, software (including microcode), firmware, or any combination of these approaches. For example, a storage medium may store thereon instructions that when executed by a machine result in performance according to any of the embodiments described herein.

At 602, a temperature associated with an IC chip is detected. For example, a signal received from the IC chip or a sensor proximate to the IC chip may be used to detect the temperature.

At 604, it is determined if the temperature exceeds a threshold. For example, a control circuit might compare a received signal to a threshold value. If the temperature does not exceed the threshold at 604, a piezoelectric fan attached to the IC chip is not activated at 606. That is, the IC chip is cool enough such that the additional cooling provided by the piezoelectric fan is not needed. If the temperature does exceed the threshold at 604, the piezoelectric fan is activated at 608 to provide additional cooling. For example, AC power may be supplied to the piezoelectric fan. According to other embodiments, a piezoelectric fan may be activated on a periodic basis (e.g., regardless of the current temperature).

According to some embodiments, an apparatus may include more than one IC chip, and each IC chip may have an attached piezoelectric fan. In this case, the method described with respect to FIG. 6 might be performed either on an apparatus-wide or chip-by-chip basis. Referring again to FIG. 4, for example, the piezoelectric fans 440 associated with some of the IC chips 410 on the bottom of the SODIMM 460 might be turned on while others are turned off.

The following illustrates various additional embodiments. These do not constitute a definition of all possible embodiments, and those skilled in the art will understand that many other embodiments are possible. Further, although the following embodiments are briefly described for clarity, those skilled in the art will understand how to make any changes, if necessary, to the above description to accommodate these and other embodiments and applications.

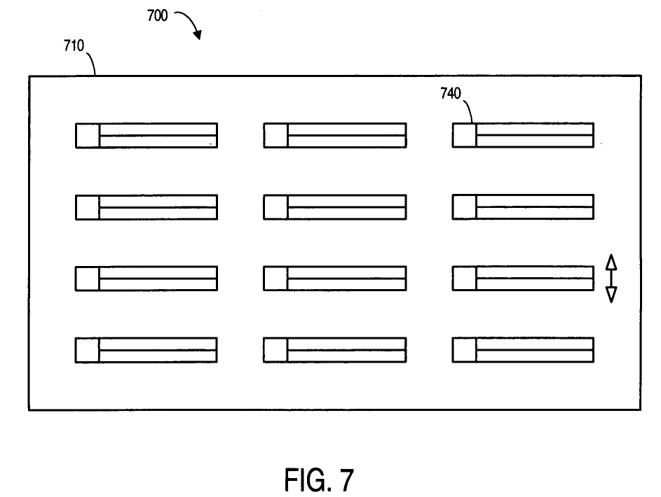

According to some embodiments described herein, a single piezoelectric fan is attached to an IC chip, and the blade moves in a direction substantially normal to a plane defined by the IC chip (e.g., as described with respect to FIGS. 1 through 5). According to other embodiments, multiple piezoelectric fans may be provided on an IC chip. For example, FIG. 7 is a block diagram of an apparatus 700 wherein a single IC chip 710 includes multiple piezoelectric fans 740. Note that some or all of the piezoelectric fans 640 might receive power through vias of the IC chip 610. Moreover, according to some embodiments a control circuit may activate a subset of the piezoelectric fans 740 (e.g., to cool a local hot spot on the IC chip 710).

Also note that the piezoelectric fans 710 in this embodiment are constructed such that the blades will vibrate within the plane defined by the IC chip 710. That is, the blades may sweep back and forth in a plane substantially parallel to the top surface of the IC chip 710. According to still another embodiment, the blades of the piezoelectric fans 710 may extend away from the surface of the IC chip 710.

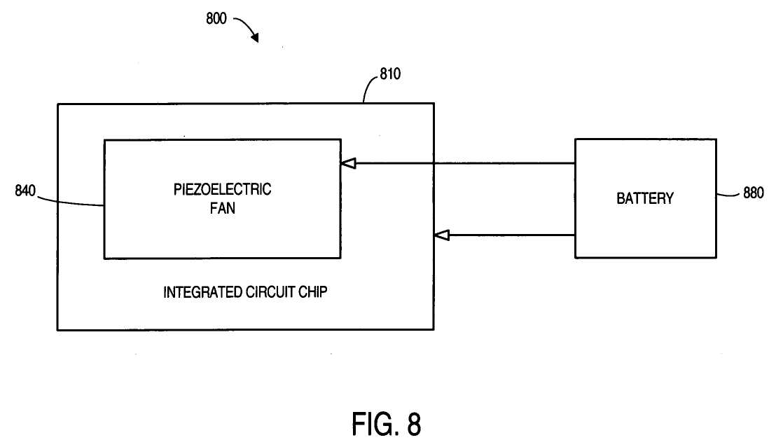

FIG. 8 is a block diagram of a system 800 according to some embodiments. The system 800 includes an IC chip 810 and an attached piezoelectric fan 740 in accordance with any of the embodiments described herein. Moreover, the system includes a battery 880 to provide power to the IC chip 810 and/or piezoelectric fan 840. According to some embodiments, a motorized blower (not illustrated in FIG. 8) may be provided in addition to the piezoelectric fan 740.

Note that a piezoelectric fan may be provided with any of a number of different types of integrated circuits in accordance with the embodiments described herein. For example, a piezoelectric fan might be attached to a processor or a memory unit, such as a Dynamic Random Access Memory (DRAM) unit, a Static Random Access Memory (SRAM) unit, and/or a volatile memory unit.

The several embodiments described herein are solely for the purpose of illustration. Persons skilled in the art will recognize from this description other embodiments may be practiced with modifications and alterations limited only by the claims.

What is claimed is:

1. An apparatus, comprising:
an integrated circuit chip; and
a piezoelectric fan attached to the integrated circuit chip.

2. The apparatus of claim 1, wherein the piezoelectric fan is to receive power through a via of the integrated circuit chip.

3. The apparatus of claim 1, wherein the piezoelectric fan is to receive power through a lead wire.

4. The apparatus of claim 1, wherein the piezoelectric fan is to receive power through at least one of: (i) a pin of the integrated circuit chip, or (ii) a package solder ball associated with the integrated circuit chip.

5. The apparatus of claim 1, wherein a portion of the piezoelectric fan is soldered to the integrated circuit chip.

6. The apparatus of claim 1, wherein the piezoelectric fan includes a flexible, non-conducting substrate.

7. The apparatus of claim 6, wherein the piezoelectric fan is a blade having a resonant frequency.

8. The apparatus of claim 7, wherein the blade is to flex at substantially the resonant frequency in a direction substantially normal to a plane defined by the integrated circuit chip.

9. The apparatus of claim 1, wherein a plurality of piezoelectric fans are attached to the integrated circuit chip.

10. The apparatus of claim 1, further comprising:
a control circuit to activate the piezoelectric fan in response to a temperature associated with the integrated circuit chip.

11. The apparatus of claim 1, wherein the integrated circuit chip comprises a memory unit.

12. The apparatus of claim 11, wherein the memory unit is one of: (i) a dynamic random access memory device, (ii) a static random access memory device, and (iii) a volatile memory device.

13. A method, comprising:
detecting a temperature associated with an integrated circuit chip; and
based on the temperature, activating a piezoelectric fan attached to the integrated circuit chip.

14. The method of claim 13, wherein said activating includes providing an alternating current to the piezoelectric fan through a via of the integrated circuit chip.

15. The method of claim 13, wherein said activating includes providing an alternating current through a lead wire.

16. The method of claim 13, wherein said activating includes providing an alternating current through at least one of: (i) a pin of the integrated circuit chip, or (ii) a package solder ball associated with the integrated circuit chip.

17. The method of claim 13, wherein there are a plurality of piezoelectric fans attached to the integrated circuit chip and said activating comprises activating a subset of the fans.

18. The method of claim 13, wherein the integrated circuit chip comprises a memory unit.

19. The method of claim 18, wherein the memory unit is one of: (i) a dynamic random access memory device, (ii) a static random access memory device, and (iii) a volatile memory device.

20. An apparatus, comprising:
a storage medium having stored thereon instructions that when executed by a machine result in the following:
determining a temperature associated with an integrated circuit chip; and
based on the temperature and the threshold value, providing power to a piezoelectric fan coupled to the integrated circuit chip.

21. The apparatus of claim 20, wherein said providing is through at least one of (i) a via of the integrated circuit chip, (ii) a lead wire to a power plane, (iii) a pin of the integrated circuit chip, or (iv) a package solder ball associated with the integrated circuit chip.

22. The apparatus of claim 20, wherein there are a plurality of piezoelectric fans attached to the integrated circuit chip, and said providing comprises:
activating a subset of the fans.

23. The apparatus of claim 20, wherein the integrated circuit chip comprises a memory unit.

24. The apparatus of claim 23, wherein the memory unit is one of: (i) a dynamic random access memory device, (ii) a static random access memory device, and (iii) a volatile memory device.

25. A system, comprising:
a board;
an integrated circuit chip being attached to the board and having a via;
a piezoelectric fan attached to the integrated circuit chip on a side opposite the board, the fan to receive power through the via; and
a battery to provide power for the system.

26. The system of claim 25, further comprising:
a control circuit to activate the piezoelectric fan in response to a temperature associated with the integrated circuit chip.

27. The system of claim 25, wherein the integrated circuit chip is associated with a memory module.

28. The system of claim 25, wherein the integrated circuit chip comprises a memory unit.

29. The system of claim 28, wherein the memory unit is one of: (i) a dynamic random access memory device, (ii) a static random access memory device, and (iii) a volatile memory device.
